(19) United States
(12) Patent Application Publication
(10) Pub. No.: US 2024/0170956 A1
(43) Pub. Date: May 23, 2024

(54) SIGNAL OUTPUT CIRCUIT AND SEMICONDUCTOR INTEGRATED CIRCUIT DEVICE

(71) Applicant: ROHM CO., LTD., Kyoto (JP)

(72) Inventors: Daisuke UCHIMOTO, Kyoto (JP); Shugo KAMINOTA, Kyoto (JP)

(21) Appl. No.: 18/507,235

(22) Filed: Nov. 13, 2023

(30) Foreign Application Priority Data
Nov. 18, 2022 (JP) 2022-184515

(51) Int. Cl. H02H 9/04; H03K 5/24

(52) U.S. Cl. CPC H02H 9/041; H03K 5/24; H03K 19/20

(57) ABSTRACT

A signal output circuit includes a comparator including a first input terminal, a second input terminal, and a third input terminal, and one of an inverter provided between an enable terminal configured to receive an enable signal and the first input terminal, and a pull-up resistor connected to the first input terminal, wherein the first input terminal is configured to be supplied with a signal based on the enable signal, wherein the second input terminal is configured to be supplied with a basis voltage, wherein the third input terminal is configured to be supplied with an abnormality detection signal, and wherein the first input terminal and the second input terminal have different polarities from each other.

### CROSS-REFERENCE TO RELATED APPLICATION

This application is based upon and claims the benefit of priority from Japanese Patent Application No. 2022-184515, filed on Nov. 18, 2022, the entire contents of which are incorporated herein by reference.

### TECHNICAL FIELD

The present disclosure relates to a signal output circuit and a semiconductor integrated circuit device including the signal output circuit.

### BACKGROUND

In the related art, there is a signal output circuit which outputs a signal indicating a comparison result of an enable signal received by an enable terminal and a basis voltage. For example, the signal output circuit is mounted on a semiconductor integrated circuit device, and the signal, which is output from the signal output circuit, is used to switch a mode of the semiconductor integrated circuit device.

### BRIEF DESCRIPTION OF DRAWINGS

The accompanying drawings, which are incorporated in and constitute a part of the specification, illustrate embodiments of the present disclosure.

FIG. 1 is a diagram showing a configuration of a signal output circuit, which outputs a signal indicating an enable state when an enable signal is supplied.

FIG. 2 is a diagram showing a configuration of a signal output circuit according to a comparative example.

FIG. 3 is a diagram showing a configuration of a signal output circuit according to a first embodiment.

FIG. 4 is a diagram showing a configuration of a signal output circuit according to a second embodiment.

FIG. 5 is a diagram showing a schematic configuration of a semiconductor integrated circuit device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the present disclosure, a MOS field effect transistor refers to a field effect transistor having a gate structure, which is formed with at least three layers of a “layer made of a conductor or a semiconductor such as polysilicon with a low resistance value,” an “insulating layer,” and a “P-type, N-type, or intrinsic semiconductor layer.” That is, the gate structure of the MOS field effect transistor is not limited to the three-layer structure of metal, oxide, and semiconductor.

In the present disclosure, a reference voltage means a voltage that is constant in an ideal state, and is actually a voltage that may vary slightly due to a change in temperature or the like.

In the present disclosure, a basis voltage means a voltage that is constant in an ideal state, and is actually a voltage that may fluctuate slightly due to a change in temperature or the like.

In the present disclosure, a constant voltage means a voltage that is constant in an ideal state, and is actually a voltage that may fluctuate slightly due to a change in temperature or the like.

<Signal Output Circuit which Outputs a Signal Indicating an Enable State when an Enable Signal is Supplied>

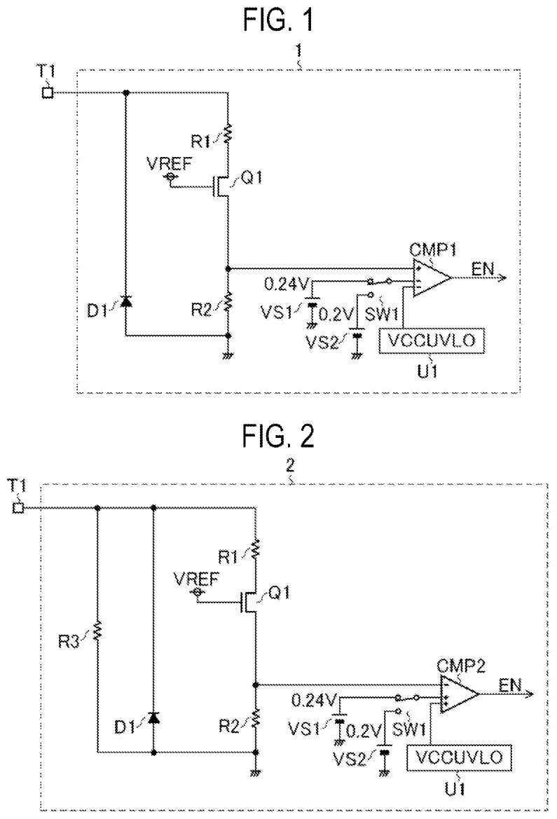

FIG. 1 is a diagram showing a configuration of a signal output circuit which outputs a signal indicating an enable state when an enable signal is supplied.

The signal output circuit 1 shown in FIG. 1 includes resistors R1 and R2, an N-channel depletion-type MOS field effect transistor Q1, a diode D1, voltage sources VS1 and VS2, a switch SW1, a low voltage detection circuit U1, and a comparator CMP1.

A first end of the resistor R1 and a cathode of the diode D1 are connected to an enable terminal T1. A second end of the resistor R1 is connected to a drain of the field effect transistor Q1. A reference voltage VREF is supplied to a gate of the field effect transistor Q1.

A source of the field effect transistor Q1 is connected to a first end of the resistor R2 and a first input terminal of the comparator CMP1. A second end of the resistor R2 and the anode of the diode D1 are fixed to a ground potential.

The diode D1 is a protection diode for absorbing EDS (Electric Die Sort) which may be applied to the enable terminal T1.

The field effect transistor Q1 is a clamp element which clamps a source voltage of the field effect transistor Q1 to a value obtained by subtracting a threshold voltage from the reference voltage VREF. Therefore, even if a high voltage is applied to the enable terminal T1 and a drain voltage of the field effect transistor Q1 increases, the field effect transistor Q1 can prevent the source voltage of the field effect transistor Q1 from increasing.

Positive electrodes of the voltage sources VS1 and VS2 are connected to a second input terminal of the comparator CMP1 via the switch SW1. Negative electrodes of the voltage sources VS1 and VS2 are fixed to the ground potential. The switch SW1 selects either the positive electrode of the voltage source VS1 or the positive electrode of the voltage source VS2 and establishes electrical connection with the second input terminal of the comparator CMP1. The voltage source VS1 outputs a first basis voltage which is a DC voltage of, for example, 0.24 V. The voltage source VS2 outputs a second basis voltage which is a DC voltage of, for example, 0.2 V.

The low voltage detection circuit U1 supplies a HIGH level signal (an example of an abnormality detection signal) to a third input terminal of the comparator CMP1 when a voltage VCC supplied to the semiconductor integrated circuit device, on which the low voltage detection circuit U1 is mounted, is a low voltage. Further, the low voltage detection circuit U1 supplies a LOW level signal to the third input terminal of the comparator CMP1 when the voltage VCC supplied to the semiconductor integrated circuit device, on which the low voltage detection circuit U1 is mounted, is not a low voltage.

As described above, the comparator CMP1 includes the first input terminal, the second input terminal, and the third input terminal. The first input terminal is a non-inverting input terminal, and the second input terminal and the third input terminal are inverting input terminals. That is, the first input terminal and the second input terminal/third input terminal have different polarities.

The comparator CMP1 outputs a signal EN which is a comparison result of a voltage supplied to the first input terminal and a higher one of a voltage supplied to the second input terminal and a voltage supplied to the third input terminal.

The signal output circuit 1 outputs a HIGH level signal EN, which is a signal indicating an enable state, when a HIGH level enable signal is supplied to the enable terminal T1. However, when the low voltage detection circuit U1 detects that the voltage VCC is a low voltage, the signal output circuit 1 outputs a LOW level signal EN.

<Signal Output Circuit according to Comparative Example>

FIG. 2 is a diagram showing a configuration of a signal output circuit according to a comparative example. The signal output circuit 2 shown in FIG. 2 is a signal output circuit which can output a signal indicating an enable state even if an enable signal is not supplied.

The signal output circuit 2 has a configuration in which the comparator CMP1 in the signal output circuit 1 is replaced with a comparator CMP2, and a resistor R3, which is a pull-down resistor, is added.

A first input terminal of the comparator CMP2 is an inverting input terminal, and second and third input terminals of the comparator CMP2 are non-inverting input terminals. The comparator CMP1 is configured to include one non-inverting input terminal and two inverting input terminals. On the other hand, the comparator CMP2 is configured to include one inverting input terminal and two non-inverting input terminals. Accordingly, a change from the comparator CMP1 to the comparator CMP2 causes a scale of change to become large.

A first end of the resistor R3 is connected to the enable terminal T1. A second end of the resistor R3 is fixed to the ground potential.

When the enable terminal T1 does not receive a HIGH level enable signal, the enable terminal T1 is fixed to the ground potential by the resistor R3 which is a pull-down resistor.

The signal output circuit 2 outputs a HIGH level signal EN, which is a signal indicating an enable state, when the HIGH level enable signal is not supplied to the enable terminal T1. Even when the low voltage detection circuit U1 detects that the voltage VCC is a low voltage, the signal output circuit 2 outputs the HIGH level signal EN.

Further, the signal output circuit 2 can output a LOW level signal EN when a HIGH level voltage is applied to the enable terminal T1. Therefore, in the semiconductor integrated circuit device including the signal output circuit 2, it is possible to measure a current flowing through the semiconductor integrated circuit device in a disable state (standby state) during EDS, thereby improving testability.

<Signal Output Circuit according to First Embodiment>

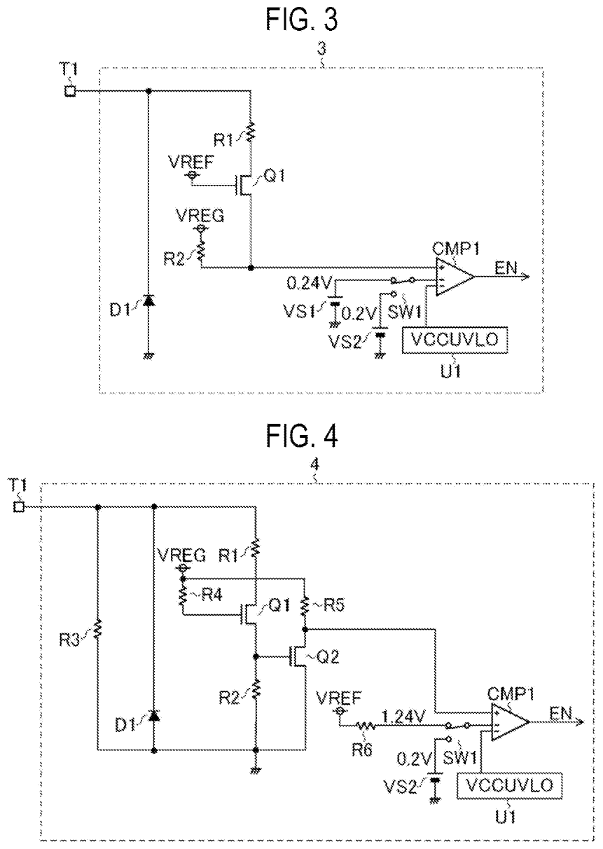

FIG. 3 is a diagram showing a configuration of a signal output circuit according to a first embodiment. The signal output circuit 3 shown in FIG. 3 is a signal output circuit that can output a signal indicating an enable state even if an enable signal is not supplied.

The signal output circuit 3 has a configuration in which the resistor R2 in the signal output circuit 1 is changed to a pull-up resistor. Specifically, the signal output circuit 3 has a configuration in which a second end of the resistor R2 is not fixed to the ground potential, but a constant voltage VREG is applied to the second end of the resistor R2. Resistance values of the resistors R1 and R2 of the signal output circuit 3 may be changed from resistance values of the resistors R1 and R2 of the signal output circuit 1. The signal output circuit 3 has few changes from the signal output circuit 1.

When a HIGH level enable signal is not supplied to the enable terminal T1, a HIGH level voltage is supplied to the first input terminal of the comparator CMP1 by the resistor R2 which is a pull-up resistor, so that the signal output circuit 3 outputs a HIGH level signal EN, which is a signal indicating an enable state.

The constant voltage VREG is set to be higher than a signal (HIGH level signal) output from the low voltage detection circuit U1 when the low voltage detection circuit U1 detects that the voltage VCC is a low voltage. Accordingly, even when the low voltage detection circuit U1 detects that the voltage VCC is a low voltage, the signal output circuit 3 outputs the HIGH level signal EN.

Further, the signal output circuit 3 can output a LOW level signal EN when a LOW level (for example, ground potential) voltage is applied to the enable terminal T1. Accordingly, in the semiconductor integrated circuit device including the signal output circuit 3, it is possible to measure a current flowing through the semiconductor integrated circuit device in a disable state (standby state) during EDS, thereby improving testability.

<Signal Output Circuit according to Second Embodiment>

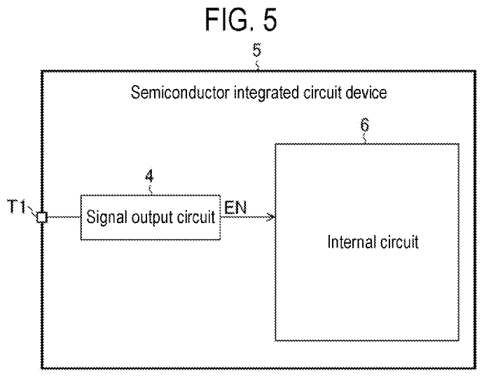

FIG. 4 is a diagram showing a configuration of a signal output circuit according to a second embodiment. The signal output circuit 4 shown in FIG. 4 is a signal output circuit that can output a signal indicating an enable state even if an enable signal is not supplied.

The signal output circuit 4 has a configuration in which a resistor R3, which is a pull-down resistor, a resistor R4, a resistor R5, and an N-channel enhancement type MOS field effect transistor Q2 are added to the signal output circuit 1, and the voltage source VS1 is replaced with a resistor R6. The resistor R5 and the MOS field effect transistor Q2 constitute an inverter. The signal output circuit 4 has few changes from the signal output circuit 1.

A first end of the resistor R3 is connected to the enable terminal T1. A second end of the resistor R3 is fixed to the ground potential.

When the enable terminal T1 does not receive a HIGH level enable signal, the enable terminal T1 is fixed to the ground potential by the resistor R3 which is a pull-down resistor.

A constant voltage VREG is applied to each of first ends of the resistors R4 and R5. A second end of the resistor R4 is connected to a gate of the MOS field effect transistor Q1. In other words, a voltage supplied to the gate of the MOS field effect transistor Q1 and a power supply voltage of the inverter are identical to each other. As a result, when a HIGH level voltage is applied to the enable terminal T1, it is possible to reliably turn on the MOS field effect transistor Q2 even in a low temperature environment.

A source of the MOS field effect transistor Q1 and the first end of the resistor R2 are connected to a gate of the MOS field effect transistor Q2. A second end of the resistor R5 is connected to a drain of the MOS field effect transistor Q2 and the first input terminal of the comparator CMP1. A source of the MOS field effect transistor Q2 is fixed to the ground potential.

A reference voltage VREF is applied to a first end of the resistor R6. The reference voltage VREF is a DC voltage of, for example, 1.24 V. The reference voltage VREF is set to be lower than the constant voltage VREG. A second end of the resistor R6 is connected to the second input terminal of the comparator CMP1 via the switch SW1. As a result, it is possible to sufficiently secure hysteresis when the level of the signal EN output from the comparator CMP1 switches.

When a HIGH level enable signal is not supplied to the enable terminal T1, a HIGH level voltage is supplied to the first input terminal of the comparator CMP1 by the inverter, so that the signal output circuit 4 outputs a HIGH level signal EN, which a signal indicating an enable state.

The constant voltage VREG is set to be higher than the signal (HIGH level signal) output from the low voltage detection circuit U1 when the low voltage detection circuit U1 detects that the voltage VCC is a low voltage. Accordingly, even when the low voltage detection circuit U1 detects that the voltage VCC is a low voltage, the signal output circuit 4 outputs the HIGH level signal EN.

Further, when a HIGH level voltage is applied to the enable terminal T1, the signal output circuit 4 can output a LOW level signal EN. Accordingly, in the semiconductor integrated circuit device including the signal output circuit 4, it is possible to measure a current flowing through the semiconductor integrated circuit device in a disable state (standby state) during EDS, thereby improving testability.

Since a circuit impedance seen from the enable terminal T1 is the same as that of the signal output circuit 1 except for the resistor R3, the signal output circuit 4 has an advantage that differences from the signal output circuit 1 are unlikely to occur in terms of ESD (Electro Static Discharge) protection, EMC (Electromagnetic Compatibility), and the like.

### <Semiconductor Integrated Circuit Device>

FIG. 5 is a diagram showing a schematic configuration of a semiconductor integrated circuit device. The semiconductor integrated circuit device 5 shown in FIG. 5 includes the enable terminal T1, the signal output circuit 4, and an internal circuit 6. In addition to the enable terminal T1, the semiconductor integrated circuit device 5 includes a terminal (not shown) for establishing electrical connection with the outside. Further, in the semiconductor integrated circuit device 5 shown in FIG. 5, the signal output circuit 3 may be provided instead of the signal output circuit 4.

The internal circuit 6 is in an enable state when the signal EN output from the signal output circuit 4 is at a HIGH level, and is in a disable state (standby state) when the signal EN output from the signal output circuit 4 is at a LOW level.

Although a function of the semiconductor integrated circuit device 5 is not limited, for example, the semiconductor integrated circuit device 5 may be a semiconductor integrated circuit device that constitutes a part or all of a linear power supply device such as an LDO (Low Drop Out).

### <Others>

The embodiments of the present disclosure can be appropriately modified in various ways within the scope of the technical ideas shown in the claims. The various embodiments described so far may be implemented in proper combination unless contradictory. The above embodiments are merely examples of the embodiments of the present disclosure, and the meanings of the terms of the present disclosure or components are not limited to those described in the above embodiments.

For example, if a withstand voltage of the comparator CMP1 is high, the signal output circuits 3 and 4 may be changed to a configuration in which the MOS field effect transistor Q1 is not provided.

For example, a circuit, which detects abnormalities other than a low voltage and outputs an abnormality detection signal, may be used instead of the low voltage detection circuit U1.

### <Supplementary Notes>

Supplementary notes are provided for the present disclosure in which specific configuration examples are shown in the above-described embodiments.

A signal output circuit (3, 4) of the present disclosure has a configuration (first configuration) which includes a comparator (CMP1) having a first input terminal, a second input terminal, and a third input terminal; and one of an inverter (Q2, R5) provided between an enable terminal configured to receive an enable signal and the first input terminal, and a pull-up resistor (R2) connected to the first input terminal, wherein the first input terminal is configured to be supplied with a signal based on the enable signal, wherein the second input terminal is configured to be supplied with a basis voltage, wherein the third input terminal is configured to be supplied with an abnormality detection signal, and wherein the first input terminal and the second input terminal have different polarities.

The signal output circuit of the first configuration may have a configuration (second configuration) which includes the inverter and further includes a pull-down resistor (R3) connected to the enable terminal.

The signal output circuit of the first or second configuration may have a configuration (third configuration) which further includes a diode (D1) having a cathode connected to the enable terminal.

The signal output circuit of any one of the first to third configurations may have a configuration (fourth configuration) which further includes a clamp element (Q1) having a first end and a second end, wherein the clamp element is provided between the enable terminal and the first input terminal, wherein the first end is arranged on an enable terminal side, and the second end is arranged on a first input terminal side, and wherein the clamp element is configured to clamp a voltage of the second end.

The signal output circuit of the fourth configuration may have a configuration (fifth configuration) which includes the inverter, wherein the clamp element is a transistor, and wherein a voltage supplied to a control end of the transistor is the same as a power supply voltage of the inverter.

A semiconductor integrated circuit device (5) of the present disclosure has a configuration (sixth configuration) which includes a signal output circuit of any one of the first to fifth configurations; and the enable terminal.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A signal output circuit comprising:
a comparator including a first input terminal, a second input terminal, and a third input terminal; and
one of an inverter provided between an enable terminal configured to receive an enable signal and the first input terminal, and a pull-up resistor connected to the first input terminal,
wherein the first input terminal is configured to be supplied with a signal based on the enable signal,
wherein the second input terminal is configured to be supplied with a basis voltage,
wherein the third input terminal is configured to be supplied with an abnormality detection signal, and
wherein the first input terminal and the second input terminal have different polarities from each other.

2. The signal output circuit of claim 1, comprising the inverter,
wherein the signal output circuit further comprises a pull-down resistor connected to the enable terminal.

3. The signal output circuit of claim 1, further comprising a diode having a cathode connected to the enable terminal.

4. The signal output circuit of claim 1, further comprising a clamp element having a first end and a second end,
wherein the clamp element is provided between the enable terminal and the first input terminal,
wherein the first end is arranged on an enable terminal side, and the second end is arranged on a first input terminal side, and
wherein the clamp element is configured to clamp a voltage of the second end.

5. The signal output circuit of claim 4, comprising the inverter,
wherein the clamp element is a transistor, and
wherein a voltage supplied to a control end of the transistor is the same as a power supply voltage of the inverter.

6. A semiconductor integrated circuit device comprising:
the signal output circuit of claim 1; and
the enable terminal.
